(19) United States
(12) Patent Application Publication
(10) Pub. No.: US 2023/0384835 A1
(43) Pub. Date: Nov. 30, 2023

(54) DISPLAY DEVICE AND METHOD OF MANUFACTURING DISPLAY DEVICE

(71) Applicant: Samsung Display Co., Ltd., Yongin-si (KR)

(72) Inventors: BYUNGHOON KANG, Yongin-si (KR); KYUNG-MAN KIM, Yongin-si (KR); SANGHOON KIM, Yongin-si (KR); SUNGHOON KIM, Yongin-si (KR); SEUNGHO KIM, Yongin-si (KR); YURI KIM, Yongin-si (KR); MIN-HOON CHOI, Yongin-si (KR); SEONGJIN HWANG, Yongin-si (KR)

(73) Assignee: Samsung Display Co., Ltd., Yongin-si (KR)

(21) Appl. No.: 18/318,765

(22) Filed: May 17, 2023

(30) Foreign Application Priority Data
May 25, 2022 (KR) 10-2022-0064346

(51) Int. Cl. G06F 1/16; H04M 1/02

(52) U.S. Cl. CPC G06F 1/1656; G06F 1/1618; H04M 1/0268; H04M 1/0222; G06F 1/1652

(57) ABSTRACT

A display device includes a display module including a folding area and a window module disposed on the display module. The window module includes a base substrate including a first surface on which a plurality of first grooves are formed and a second surface on which a plurality of second grooves are formed, a first cover layer disposed on the first surface of the base substrate and filled in the plurality of first grooves, and a second cover layer disposed on the second surface of the base substrate and filled in the plurality of second grooves. Depths of the plurality of first grooves and the plurality of second grooves are greater than or equal to half of a distance between the first surface and the second surface.

### CROSS-REFERENCE TO RELATED APPLICATION(S)

This application claims priority to and benefits of Korean Patent Application No. 10-2022-0064346 under 35 U.S.C. § 119, filed on May 25, 2022, in the Korean Intellectual Property Office (KIPO), the entire contents of which are incorporated herein by reference.

### BACKGROUND

### 1. Technical Field

Embodiments relate to a display device including a window module having improved folding reliability and a method of manufacturing the display device.

### 2. Description of the Related Art

An electronic device displays various images on a display screen and provides information to a user. In general, the electronic device displays information on an allocated screen. Nowadays, flexible electronic devices including a flexible display panel are being developed. Unlike a rigid electronic device, a flexible electronic device is foldable, rollable, or bendable. The flexible electronic device, of which shape is changeable in various ways, may be carried regardless of the size of a screen, and thus user convenience may be improved.

In case that a structure for implementing the flexibility of the flexible electronic device is applied to the flexible electronic device, the durability of the flexible electronic device against impact may be weakened. Furthermore, in case that a structure for strengthening the durability of the flexibility electronic device against impact is applied to the flexible electronic device, the flexibility of the flexibility electronic device may be deteriorated.

### SUMMARY

Embodiments provide a display device including a window module having improved folding reliability and a method of manufacturing the display device.

However, embodiments of the disclosure are not limited to those set forth herein. The above and other embodiments will become more apparent to one of ordinary skill in the art to which the disclosure pertains by referencing the detailed description of the disclosure given below.

According to an embodiment, a display device may include a display module including a folding area and a window module disposed on the display module. The window module may include a base substrate including a first surface on which a plurality of first grooves are formed and a second surface on which a plurality of second grooves are formed, a first cover layer disposed on the first surface of the base substrate and filled in the plurality of first grooves, and a second cover layer disposed on the second surface of the base substrate and filled in the plurality of second grooves. Depths of the plurality of first grooves and the plurality of second grooves are greater than or equal to half of a distance between the first surface and the second surface of the base substrate.

The window module may further include a third cover layer that covers a plurality of side surfaces of the base substrate connecting the first surface and the second surface, and the base substrate may be covered by the first cover layer, the second cover layer, and the third cover layer.

Refractive indexes of the first cover layer, the second cover layer, and the third cover layer may be in a range of about 1.49 to about 1.53.

Poisson's ratios of the first cover layer, the second cover layer, and the third cover layer may be in a range of about 0.3 to about 0.6.

Young's moduli of the first cover layer, the second cover layer, and the third cover layer may be in a range of about 20 kPa to about 50 kPa.

Volumetric strains of the first cover layer, the second cover layer, and the third cover layer may be in a range of about 5% to about 20% in case that the display module and the window module are folded.

The first cover and the second cover may be thinner than the third cover layer.

The first cover layer and the second cover layer may have a thickness of about 20 micrometers to about 40 micrometers, and the third cover layer may have a thickness of about 90 micrometers to about 110 micrometers.

A plurality of concave grooves recessed toward the plurality of second grooves, respectively, may be formed in the second cover layer in a folded state in which the display module and the window module are folded.

Depths of the plurality of concave grooves may be smaller than depths of the plurality of second grooves.

Widths of the plurality of first grooves and widths of the plurality of second grooves may be decreased as being closer to first bottom surfaces of the plurality of first grooves and second bottom surfaces of the plurality of second grooves.

The base substrate may have a thickness of about 200 micrometers to about 400 micrometers.

The second surface of the base substrate may be disposed between the first surface of the base substrate and the display module. The plurality of first grooves may have first width in a flat state in which the display module and the window module are flat, and the plurality of first grooves may have second widths in a folded state in which the display module and the window module are folded. The second widths of the plurality of first grooves in the folded state may be smaller than the first widths of the plurality of first grooves in the flat state.

The plurality of second grooves may have third widths in the flat state in which the display module and the window module are flat, and the plurality of second grooves may have fourth widths in the folded state in which the display module and the window module are folded. The fourth widths of the plurality of second grooves in the folded state may be greater than the third widths of the plurality of second grooves in the flat state.

According to an embodiment, a display device may include a display module including a folding area and a window module disposed on the display module. The window module may include a base substrate including a first surface on which a plurality of first grooves are formed, a second surface on which a plurality of second grooves are formed, and a plurality of side surfaces connecting the first surface and the second surface, a first cover layer disposed on the first surface of the base substrate and filled in the plurality of first grooves, a second cover layer disposed on the second surface of the base substrate and filled in the plurality of second grooves, and a third cover layer covering the plurality of side surfaces. The base substrate may be covered by the first cover layer, the second cover layer, and the third cover layer, and a plurality of concave grooves may be recessed toward the plurality of second grooves, respectively, and may be formed in the second cover layer in a folded state in which the display module and the window module are folded.

Depths of the plurality of first grooves and the plurality of second grooves may be greater than or equal to half of a distance between the first surface and the second surface.

Depths of the plurality of concave grooves may be smaller than depths of the plurality of second grooves.

Widths of the plurality of first grooves and widths of the plurality of second grooves may be decreased as being closer to first bottom surfaces of the plurality of first grooves and second bottom surfaces of the plurality of second grooves.

Refractive indexes of the first cover layer, the second cover layer, and the third cover layer may be in a range of about 1.49 to about 1.53.

Poisson's ratios of the first cover layer, the second cover layer, and the third cover layer may be in a range of about 0.3 to about 0.6.

Young's moduli of the first cover layer, the second cover layer, and the third cover layer may be in a range of about 20 kPa to about 50 kPa.

Volumetric strains of the first cover layer, the second cover layer, and the third cover layer may be in a range of about 5% to about 20% in case that the display module and the window module are folded.

The second surface of the base substrate may be disposed between the first surface of the base substrate and the display module. The plurality of first grooves may have first widths in a flat state in which the display module and the window module are flat, and the plurality of first grooves may have second widths in a folded state in which the display module and the window module are folded. The second widths of the plurality of first grooves in the folded state may be smaller than the first widths of the plurality of first grooves in the flat state. The plurality of second grooves may have third widths in the flat state in which the display module and the window module are flat, and the plurality of second grooves may have fourth widths in the folded state in which the display module and the window module are folded. The fourth widths of the plurality of second grooves in the folded state may be greater than the third widths of the plurality of second grooves in the flat state.

The first cover layer and the second cover layer may have a thickness of about 20 micrometers to about 40 micrometers, and the third cover layer may have a thickness of about 90 micrometers to about 110 micrometers.

According to an embodiment, a method for manufacturing a display device may include forming a display module, forming a window module, and attaching the window module to the display module. The forming of the window module may include placing a base substrate on a carrier film, the base substrate including a first surface on which a plurality of first grooves are formed, a second surface on which a plurality of second grooves are formed, and a plurality of side surfaces connecting the first surface and the second surface, attaching a guide film to the carrier film, the guide film having an opening formed therein to surround the base substrate, forming an upper preliminary cover layer covering the first surface and the plurality of side surfaces of the base substrate, forming a lower preliminary cover layer covering the second surface, and cutting a portion of the upper preliminary cover layer and a portion of the lower preliminary cover layer along a cutting line.

The cutting line may be spaced apart from the plurality of side surfaces.

The forming of the upper preliminary cover layer may include applying a first resin material to the first surface of the base substrate and placing a first protective module on the first resin material, the first protective module including a protective layer and a planarization substrate, disposing the protective layer in close contact with the first resin material by rolling an upper surface of the first protective module, removing the planarization substrate from the protective layer, turning the carrier film, the base substrate, and the protective layer upside down such that positions of the first surface and the second surface are interchanged, and curing the first resin material.

The forming of the lower preliminary cover layer may include removing the carrier film from the base substrate, applying a second resin material to the second surface of the base substrate, attaching a second protective module to the second resin material, the second protective module including a release paper film and a planarization substrate, disposing the release paper film in close contact with the second resin material by rolling an upper surface of the second protective module, removing the planarization substrate from the release paper film, and curing the second resin material.

The first protective module may further include an adhesive layer, and the adhesive layer may be disposed under the protective layer.

A depth of the opening of the guide film may be greater than or equal to a height of the base substrate, and the base substrate may be disposed in the opening of the guide film.

The guide film may include a flow passage provided on a side surface of the guide film.

A length of the cutting line may be longer than a perimeter of the base substrate.

### BRIEF DESCRIPTION OF THE DRAWINGS

The above and other objects and features of the disclosure will become apparent by describing in detail embodiments thereof with reference to the accompanying drawings.

FIG. 1 is a schematic perspective view of a display device according to an embodiment.

FIG. 2A is a schematic view illustrating an in-folded state of the display device according to an embodiment.

FIG. 2B is a schematic view illustrating an out-folded state of the display device according to an embodiment.

FIG. 3A is a schematic sectional view of the display device according to an embodiment.

FIG. 3B is a schematic enlarged view illustrating an area AA′ of FIG. 3A.

FIG. 4 is a schematic sectional view illustrating a folded state of the display device according to an embodiment.

FIG. 5A is a sectional view of a portion of a bent window module according to an embodiment.

FIG. 5B is a graph illustrating a portion corresponding to an area BB′ of FIG. 5A.

FIG. 6 is a flowchart illustrating a display device manufacturing method according to an embodiment.

FIGS. 7 to 16B are schematic views illustrating portions of the display device manufacturing method according to an embodiment.

FIG. 17 is a schematic sectional view illustrating a window module and a release paper film according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to the accompanying drawings.

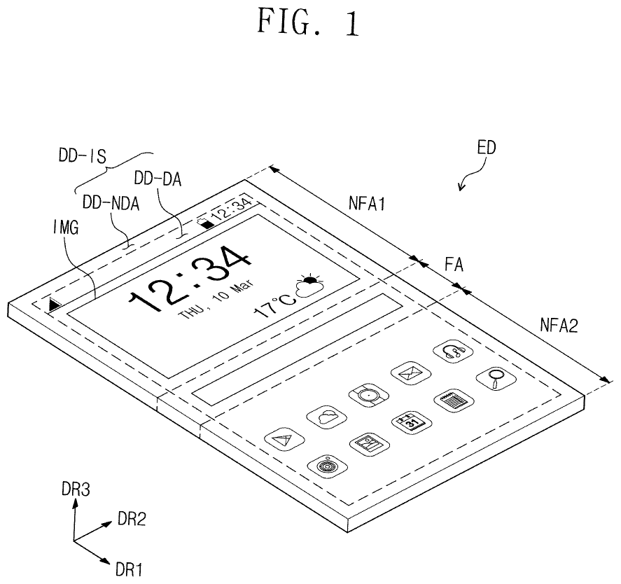

FIG. 1 is a schematic perspective view of a display device ED according to an embodiment.

Referring to FIG. 1, the display device ED may display an image IMG through a display surface DD-IS. A clock window image, a search window image, and icon images are illustrated as examples of the image IMG. The display surface DD-IS may be parallel to a plane defined by a first direction DR1 and a second direction DR2. The normal direction of the display surface DD-IS (e.g., the thickness direction of the display device ED) is indicated by a third direction DR3. Front surfaces (or upper surfaces) and rear surfaces (or lower surfaces) of members or units to be described below are distinguished from each other based on the third direction DR3.

The display surface DD-IS may include a display area DD-DA on which the image IMG is displayed and a non-display area DD-NDA adjacent to the display area DD-DA. The non-display area DD-NDA may be an area on which no image is displayed. The display area DD-DA may have a rectangular shape. The non-display area DD-NDA may surround the display area DD-DA. However, embodiments are not limited thereto, the shape of the display area DD-DA and the shape of the non-display area DD-NDA may be relatively designed. In another example, the non-display area DD-NDA may be omitted.

In FIG. 1, a portable electronic device is illustrated as an example of the display device ED. However, embodiments are not limited thereto, and the display device ED may be used in small and medium-sized electronic devices, such as a mobile phone, a tablet computer, a car navigation unit, a game machine, a smart watch, and the like, as well as large electronic devices such as a television, a monitor, and the like.

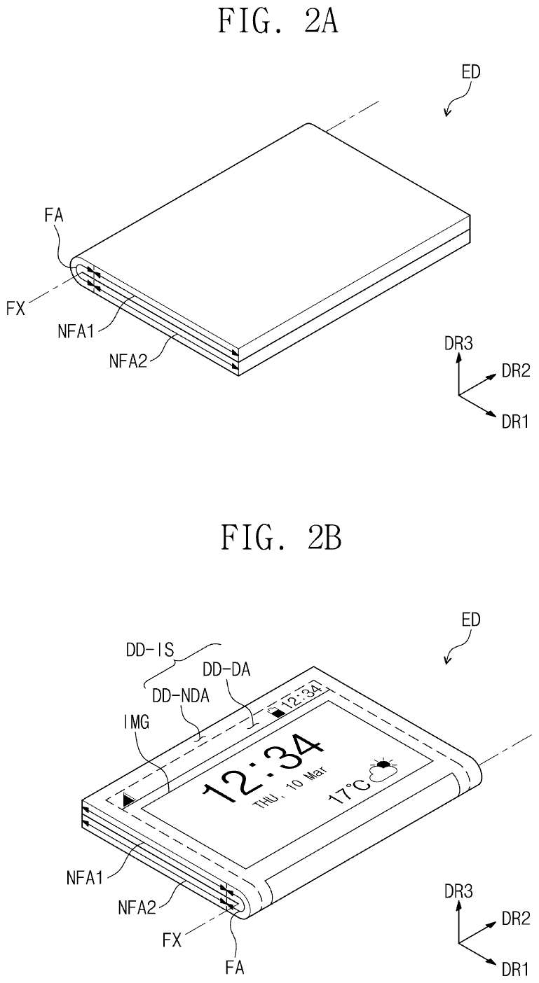

FIG. 2A is a schematic view illustrating an in-folded state of the display device ED according to an embodiment. FIG. 2B is a schematic view illustrating an out-folded state of the display device ED according to an embodiment.

Referring to FIG. 2A, the display device ED may include areas defined according to operation types. The display device ED may include a first non-folding area NFA1, a second non-folding area NFA2, and a folding area FA disposed between the first non-folding area NFA1 and the second non-folding area NFA2. The folding area FA may be folded on the basis of a folding axis FX and may substantially form a curvature.

The display device ED according to an embodiment may be folded in an in-folding manner such that the display surface DD-IS of the first non-folding area NFA1 and the display surface DD-IS of the second non-folding area NFA2 may face each other.

Referring to FIG. 2B, the display device ED may be folded in an out-folding manner such that the display surface DD-IS may be exposed to the outside. The folding axis FX may extend in the second direction DR2. The folding axis FX may face in a short axis direction of the display device ED.

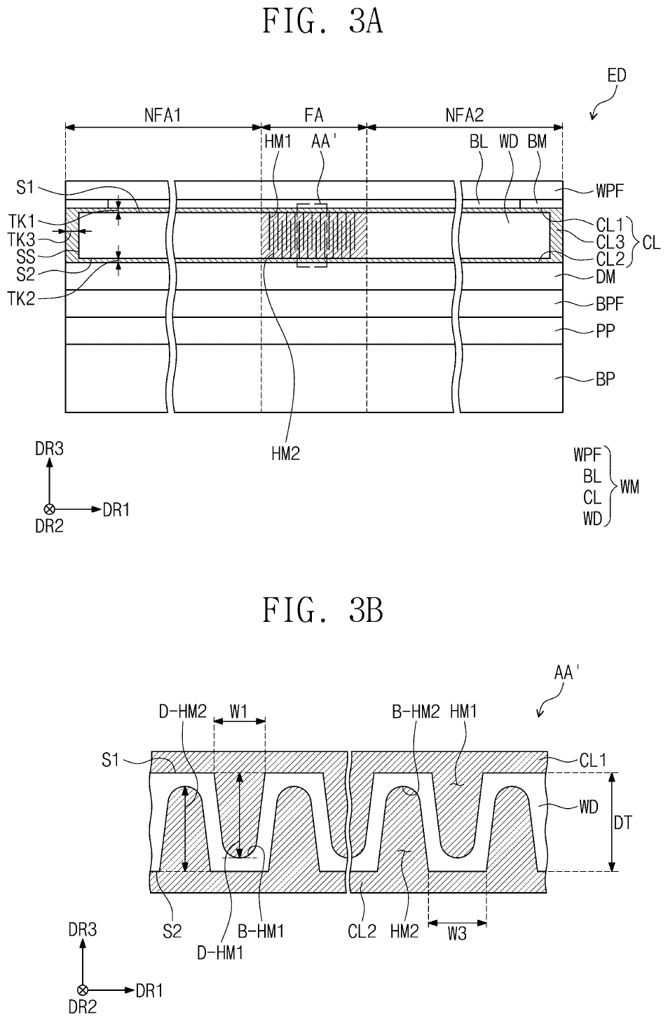

FIG. 3A is a schematic sectional view of the display device ED according to an embodiment. FIG. 3B is a schematic enlarged view illustrating an area AA′ of FIG. 3A.

Referring to FIG. 3A, the display device ED may include a window module WM, a display module DM, a protective film BPF, a protective panel PP, and a lower member BP. The display device ED may be a flexible display device ED. Accordingly, the window module WM, the display module DM, the protective film BPF, the protective panel PP, and the lower member BP may each have a flexible property. The display device ED may include the first non-folding area NFA1, the second non-folding area NFA2, and the folding area FA.

The window module WM may be disposed on the display module DM. The window module WM may include a protective layer WPF, an adhesive layer BL, a window WD, and a cover layer CL.

The window WD may be disposed on the display module DM. The window WD may be referred to as a base substrate WD. The window WD may protect the display module DM from external impacts and scratches. The window WD may include an optically clear insulating material. For example, the window WD may include thin glass. An image generated on the display module DM may be provided to a user through the window WD. The window WD may have a single-layer structure or a multi-layer structure. For example, the window WD may include at least one of a touch screen film and an optical film. The optical film may be, for example, a polarizer film, a diffusion film, or a protective film.

Referring to FIGS. 3A and 3B, the window WD may include a first surface S1, a second surface S2, and side surfaces SS. The first surface S1 of the window WD may be spaced apart from the display module DM with the second surface S2 therebetween, and the second surface S2 may face the display module DM. For example, the second surface S2 may be disposed between the first surface S1 and the display module DM. The side surfaces SS may connect the first surface S1 and the second surface S2. First grooves HM1 may be formed on the first surface S1 of the window WD that overlaps the folding area FA, and second grooves HM2 may be formed on the second surface S2 of the window WD that overlaps the folding area FA.

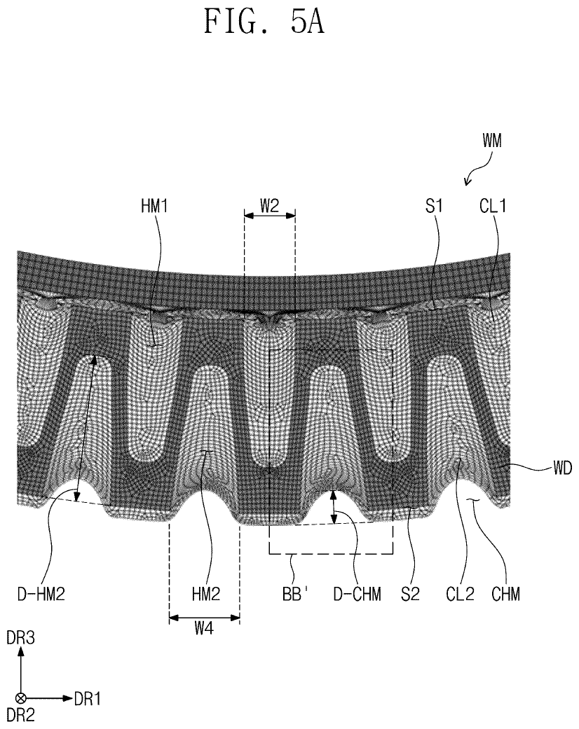

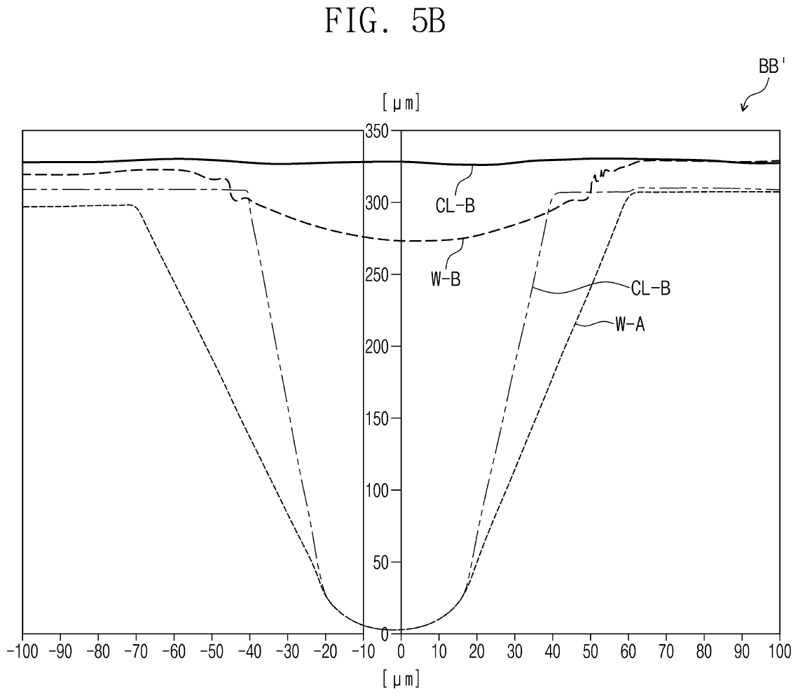

The depths D-HM1 and D-HM2 of the first grooves HM1 and the second grooves HM2 may be greater than or equal to half of the distance DT between the first surface S1 and the second surface S2. For example, the depths D-HM1 of the first grooves HM1 may be a distance between first bottom surfaces B-HM1 of the first grooves HM1 and a first virtual surface, which is coplanar with the the first surface S1 in the third direction DR3. For example, the depths D-HM2 of the second grooves HM2 may be a distance between second bottom surfaces B-HM2 of the second grooves HM2 and a second virtual surface, which is coplanar with the the second surface S2 in the third direction DR3. For example, when viewed from a side, some of the first grooves HM1 may overlap some of the second grooves HM2. According to the above-described configuration, a repulsive force applied to the folding area FA during folding may be decreased, and a tensile force may be increased. The widths (e.g., W1 and W2 in FIGS. 3B and 5A) of the first grooves HM1 and the widths (e.g., W3 and W4 in FIGS. 3B and 5A) of the second grooves HM2 may be decreased as being closer to the first bottom surfaces B-HM1 of the first grooves HM1 and the second bottom surfaces B-HM2 of the second grooves HM2.

The cover layer CL may be disposed between the adhesive layer BL and the display module DM. The cover layer CL may include a first cover layer CL1, a second cover layer CL2, and a third cover layer CL3. The first cover layer CL1 and the third cover layer CL3 may be referred to as an upper cover layer UCL (refer to FIG. 17), and the second cover layer CL2 may be referred to as a lower cover layer CL2. The first cover layer CL1 may be disposed on the first surface S1 of the base substrate WD, and the second cover layer CL2 may be disposed on the second surface S2 of the base substrate WD. The third cover layer CL3 may be disposed between the adhesive layer BL and the display module DM and may be contact with (e.g., direct contact with) the side surfaces SS of the window WD.

The thickness TK1 of the first cover layer CL1 and the thickness TK2 of the second cover layer CL2 may be smaller than the thickness TK3 of the third cover layer CL3. The thickness TK1 of the first cover layer CL1 and the thickness TK2 of the second cover layer CL2 may be in a range of about 20 micrometers to about 40 micrometers, and the thickness TK3 of the third cover layer CL3 may be in a range of about 90 micrometers to about 110 micrometers.

The refractive indexes of the first cover layer CL1, the second cover layer CL2, and the third cover layer CL3 may be in a range of about 1.49 to about 1.53. The refractive indexes may be equal or similar to the refractive index of the window WD. As the refractive indexes of the first to third cover layers CL1, CL2, and CL3 are similar to the refractive index of the window WD, the first grooves HM1 and the second grooves HM2 formed in the window WD may not be visible from the outside.

In case that the display device ED is folded, the first to third cover layers CL1, CL2, and CL3 may be stretched (or extended) and contracted (or compressed). Poisson's ratio may represent the ratio of transverse strain to longitudinal strain in case that a material is subjected to vertical stress in a direction. In case that the display device ED including the base substrate WD having a thickness of about 200 micrometers to about 400 micrometers is folded, the Poisson's ratios of the first to third cover layers CL1, CL2, and CL3 may be in a range of about 0.3 to about 0.6. However, the Poisson's ratios of the first to third cover layers CL1, CL2, and CL3 may vary according to the thickness of the base substrate WD.

Young's modulus is a mechanical property that measures the stiffness of a solid material. The Young's modulus refers to a property of the material to resist elastic deformation. Accordingly, the Young's modulus may have a value according to physical properties of the material. In case that the display device ED including the base substrate WD having a thickness of about 200 micrometers to about 400 micrometers is folded, the Young's moduli of the first to third cover layers CL1, CL2, and CL3 may be in a range of about 20 kPa to about 50 kPa.

Volumetric strain represents the ratio of a deformed volume to an original volume in case that an object is deformed by an external force. In case that the display device ED including the base substrate WD having a thickness of about 200 micrometers to about 400 micrometers is folded, the volumetric strains of the first to third cover layers CL1, CL2, and CL3 may be in a range of about 5% to about 20%. For example, the first to third cover layers CL1, CL2, and CL3 may have a transverse strain of about 33% and a longitudinal strain of about 17%. However, this is illustrative, and the transverse strain and the longitudinal strain may vary according to the shapes, widths, depths, and physical properties of the first grooves HM1 and the second grooves HM2.

The cover layer CL may cover the first surface S1, the second surface S2, and the side surfaces SS of the window WD. For example, the first cover layer CL1 may cover the first surface S1 of the window WD and may fill the first grooves HM1. The second cover layer CL2 may cover the second surface S2 of the window WD and may fill the second grooves HM2. The third cover layer CL3 may cover the side surfaces SS. For example, the window WD (e.g., the base substrate) may be covered (e.g., completely covered) by the first cover layer CL1, the second cover layer CL2, and the third cover layer CL3.

As the cover layer CL has a structure surrounding the window WD, a phenomenon, in which the shapes of the first grooves HM1 and the second grooves HM2 formed in the folding area FA are viewed from the outside, may be reduced. For example, an effect of improving the durability of the window module WM may be achieved.

The protective layer WPF may be referred to as a window protection film WPF. As the protective layer WPF is attached to the cover layer CL, the impact resistance of the display device ED may be improved. The protective layer WPF may protect components disposed under the protective layer WPF. A hard coating layer, an anti-fingerprint layer, and the like may be additionally included in the protective layer WPF to improve characteristics such as chemical resistance, wear resistance, and the like. The protective layer WPF may include a transparent material.

The protective layer WPF may include a light blocking material BM. The light blocking material BM of the protective layer WPF may overlap the non-display area DD-NDA (refer to FIG. 1) of the display device ED. The light blocking material BM may be a material through which light cannot pass.

The adhesive layer BL may be disposed between the window WD and the protective layer WPF. The adhesive layer BL may be an optically clear adhesive film, an optically clear resin, or a pressure sensitive adhesive film. Although FIG. 3A illustrates an example that the adhesive layer BL is disposed between the window WD and the protective layer WPF, an adhesive film may be disposed between the window module WM and the display module DM. In another example, the adhesive layer BL may be omitted. For example, the protective layer WPF may be disposed (e.g., directly disposed) on the window WD, and the window module WM may be disposed (e.g., directly disposed) on the display module DM.

The display module DM may include the first non-folding area NFA1, the second non-folding area NFA2, and the folding area FA. The display module DM may include a display panel, a sensing unit, and an anti-reflection layer. In another example, at least one of the sensing unit and the anti-reflection layer may be omitted. For example, the display module DM may include only the display panel. The display panel may be an emissive display panel. However, embodiments are not limited thereto. For example, the display panel may be an organic light emitting display panel or a quantum-dot light emitting display panel. An emissive layer of the organic light emitting display panel may include an organic light emitting material. An emissive layer of the quantum-dot light emitting display panel may include quantum dots or quantum rods.

The protective film BPF may be referred to as a lower protective film BPF. The protective film BPF may be disposed under the display module DM. The protective film BPF may prevent scratches on the rear surface of the display module DM during a process of manufacturing the display module DM. The protective film BPF may be a colored polyimide film. For example, the protective film BPF may be an opaque yellow film. However, the material of the protective film BPF is not limited to any one example as long as it is flexible and is able to protect the lower portion of the display module DM.

The protective panel PP may be disposed under the protective film BPF. The lower member BP may be disposed under the protective panel PP. As the protective panel PP and the lower member BP are attached to the bottom of the protective film BPF, the impact resistance of the display device ED may be improved. The protective panel PP and the lower member BP may protect components disposed on the protective panel PP. The lower member BP may include a functional layer such as a cushion layer.

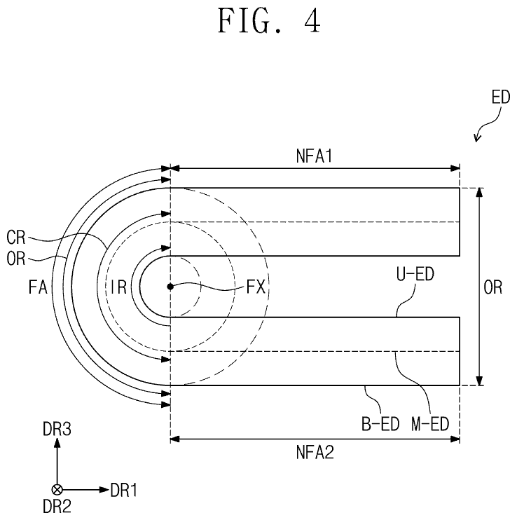

FIG. 4 is a schematic sectional view illustrating a folded state of the display device ED according to an embodiment.

Referring to FIG. 4, the display device ED may be folded on the basis of the folding axis FX extending in the second direction DR2. In case that the display device ED is folded, a semi-circumference IR of a circle defined by an upper surface U-ED of the display device ED may be an inner semi-circumference IR. The term “semi-circumference” may be defined as a portion corresponding to half of the circumference. In case that the display device ED is folded, a semi-circumference OR of a circle defined by a lower surface B-ED of the display device ED may be an outer semi-circumference OR. A semi-circumference CR of a circle defined by a mid-plane M-ED of the display device ED may be a central semi-circumference CR.

The central semi-circumference CR may correspond to a length in which internal structures of the display device ED are not stretched or contracted. For example, internal structures of the display device ED disposed between the central semi-circumference CR and the inner semi-circumference IR may be contracted, and internal structures of the display device ED disposed between the central semi-circumference CR and the outer semi-circumference OR may be stretched. Accordingly, the internal structures of the display device ED may require a property of being stretched or contracted.

For example, the radius of the circle defined by the upper surface U-ED of the display device ED may be required to be about 1.5 mm. In case that the window WD, which is one of the internal structures of the display device ED, has a thickness of about 400 micrometers, the cover layer CL (refer to FIG. 3A) may be contracted or stretched with covering the window WD. The window module WM, which is folded, may be improved durability and a reduced repulsive force, compared to that in the related art. The thickness of the window WD and the inner semi-circumference IR have been described as examples. The thickness of the window WD and the inner semi-circumference IR may vary according to characteristics (e.g., the size and the thickness) of the display device ED.

FIG. 5A is a sectional view of a portion of the bent window module WM according to an embodiment. FIG. 5B is a graph illustrating a portion corresponding to an area BB′ of FIG. 5A. A graph CL-B before deformation of the cover layer CL, a graph CL-A after the deformation of the cover layer CL, a graph W-B before deformation of the window WD (refer to FIG. 5A), and a graph W-A after the deformation of the window WD are illustrated in FIG. 5B.

Referring to FIGS. 5A and 5B, in case that the display module DM (refer to FIG. 3A) and the window module WM are folded (e.g., in a folded state), concave grooves CHM corresponding to the second grooves HM2, respectively, may be formed in the second cover layer CL2. For example, in the folded state, the concave grooves CHM may be recessed toward the second grooves HM2, respectively. The depths D-CHM of the concave grooves CHM may be smaller than the depths D-HM2 of the second grooves HM2. The widths and depths D-CHM of the concave grooves CHM may vary according to the positions of the first grooves HM1, the positions of the second grooves HM2, and a degree of bending.

Referring to FIGS. 3B and 5A, in a flat state in which the display module DM and the window module WM are flat, the first grooves HM1 may have first widths W1, and the second grooves HM2 may have third widths W3. In a folded state in which the display module DM and the window module WM are folded, the first grooves HM1 may have second widths W2, and the second grooves HM2 may have fourth widths W4. The second widths W2 of the first grooves HM1 in the folded state may be smaller than the first widths W1 of the first grooves HM1 in the flat state. The fourth widths W4 of the second grooves HM2 in the folded state may be greater than the third widths W3 of the second grooves HM2 in the flat state.

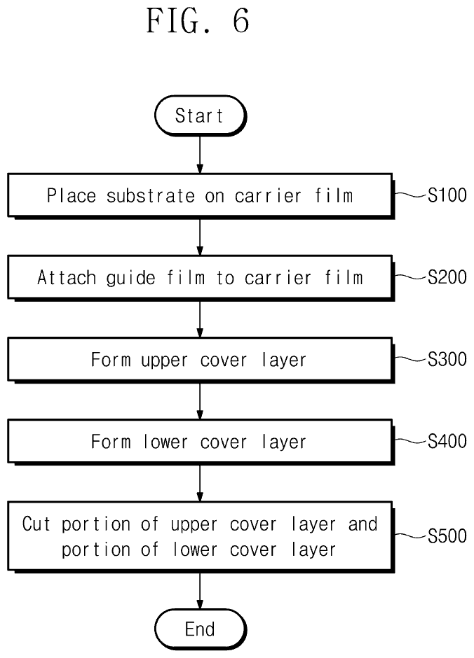

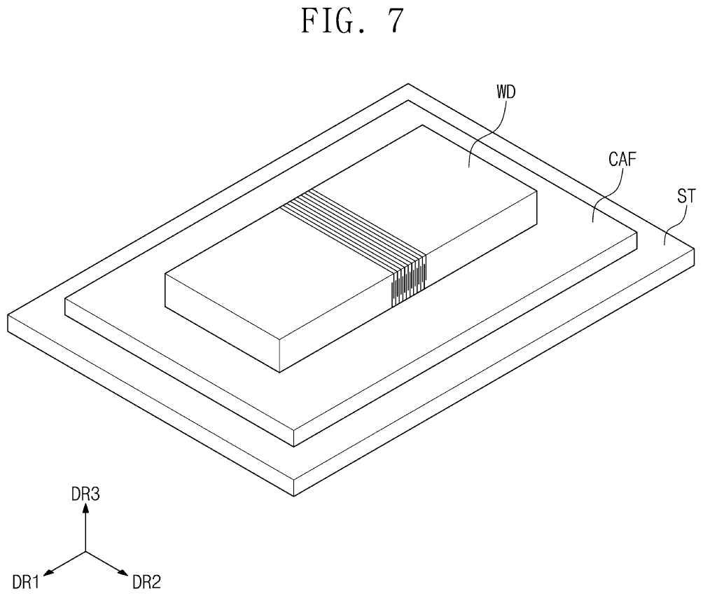

FIG. 6 is a flowchart illustrating a display device manufacturing method according to an embodiment. FIGS. 7 to 16B are schematic views illustrating portions of the display device manufacturing method according to an embodiment.

Referring to FIGS. 3A, 6, and 7, the display device manufacturing method may include a step of forming a display module DM, a step of forming a window module WM, and a step of attaching the window module WM and the display module DM to each other. However, the sequence is illustrative, and the sequence of the step of forming the display module DM and the step of forming the window module WM may be changed or modified. A process of forming the window module WM will be described below.

A carrier film CAF may be disposed on a stage ST. A base substrate WD (e.g., a window) may be disposed on the carrier film CAF (S100). The base substrate WD may include a first surface S1 on which first grooves HM1 are formed, a second surface S2 on which second grooves HM2 are formed, and side surfaces SS connecting the first surface S1 and the second surface S2.

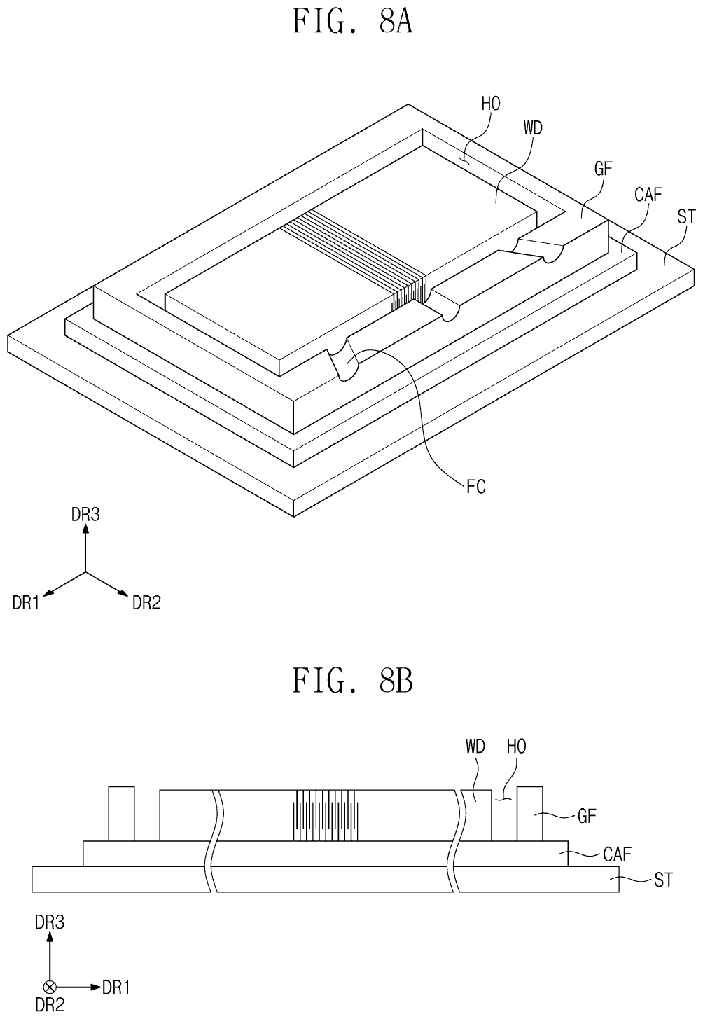

Referring to FIGS. 6, 8A, and 8B, a guide film GF may be attached to the carrier film CAF (S200). An opening HO surrounding the base substrate WD may be formed in the guide film GF, and a flow passage FC may be provided on a side surface of the guide film GF. The base substrate WD may be disposed in the opening HO of the guide film GF. The depth of the opening HO may be greater than or equal to the height (or thickness) of the base substrate WD. The depth of the flow passage FC may be smaller than the depth of the opening HO. The flow passage FC may be a component for preventing a material filling the opening HO from overflowing the upper surface of the guide film GF.

Referring to FIGS. 6 and 9 to 12B, an upper cover layer UCL (refer to FIG. 17) may be formed on the base substrate WD (S300). The upper cover layer UCL may cover the first surface S1 and the side surfaces SS.

Referring to FIGS. 6, 9, 10A, and 10B, a first resin material CL_I1 may be applied to the first surface S1 of the base substrate WD. For example, the first resin material CL_I1 may be evenly applied to the first surface S1, and a portion of the first resin material CL_I1 may fill the opening HO of the guide film GF. The first resin material CL_I1, which is applied to the first surface S1 and fills the opening HO, may form a first preliminary cover layer CL1_I and a third preliminary cover layer CL3_I. The first preliminary cover layer CL1_I and the third preliminary cover layer CL3_I may form an upper preliminary cover layer UCL_I.

A first protective module PM1 may be disposed on the first resin material CL_I1. As illustrated in FIG. 10A, the first protective module PM1 may be disposed with an inclination on the base substrate WD to which the first resin material CL_I1 is applied. The first protective module PM1 may include an adhesive layer BL, a protective layer WPF, a protective film PPF, and a planarization substrate FTW.

The adhesive layer BL may be disposed between the protective layer WPF and the first preliminary cover layer CL1_I and may attach the protective layer WPF and the first preliminary cover layer CL1_I to each other. The protective layer WPF attached to the base substrate WD may protect components disposed under the protective layer WPF. The protective film PPF may be disposed between the planarization substrate FTW and the protective layer WPF and may prevent damage to the protective layer WPF. The planarization substrate FTW may be a component disposed at the top of the first protective module PM1.

The upper surface of the first protective module PM1 may be rolled by a roller RR. For example, the roller RR may roll the upper surface of the planarization substrate FTW. Thus, the protective layer WPF may be disposed in close contact with the first resin material CL_I1. By using the planarization substrate FTW, constant pressure may be evenly applied to the entire surface to which the first resin material CL_I1 is applied. The upper surfaces of the first preliminary cover layer CL1_I and the third preliminary cover layer CL3_I may be flattened through a planarization process. The rolling process may be performed in a chamber CHB. The inside of the chamber CHB may be in a vacuum state.

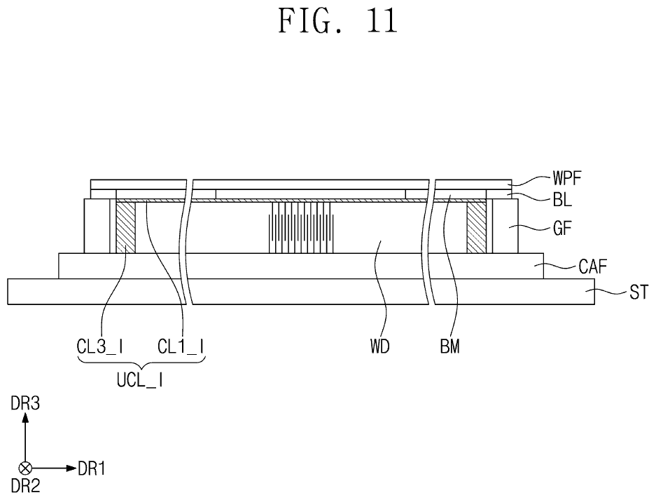

Referring to FIGS. 6 and 11, the planarization substrate FTW may be removed from the protective layer WPF. At this time, the protective film PPF may also be removed from the protective layer WPF. The protective film PPF disposed between the planarization substrate FTW and the protective layer WPF may prevent scratches on the protective layer WPF that occur in the rolling process and the process of removing the planarization substrate FTW. Thereafter, the carrier film CAF, the base substrate WD, and the protective layer WPF may be turned upside down such that the positions the first surface S1 and the second surface S2 of the base substrate WD may be interchanged.

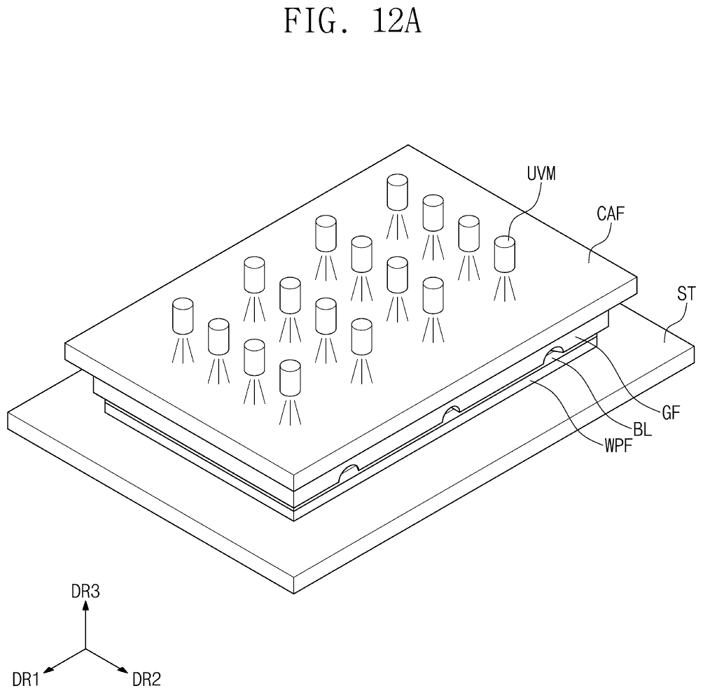

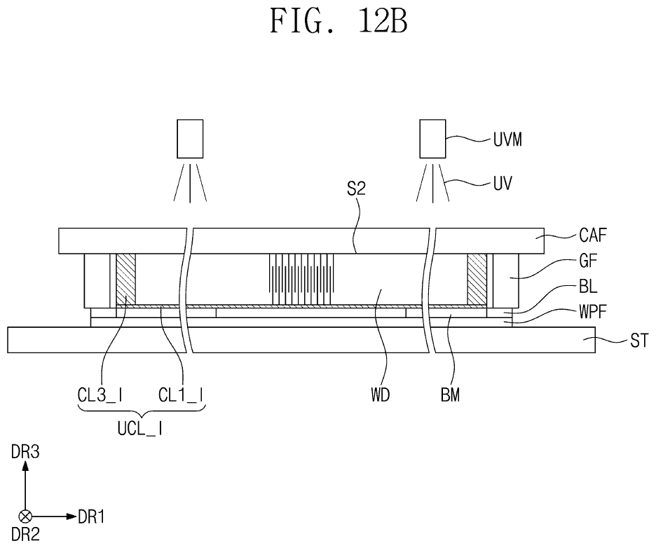

Referring to FIGS. 6, 12A, and 12B, the first resin material CL_I1 may be cured by a curing device UVM. The curing device UVM may emit ultraviolet (UV) light toward the second surface S2 of the base substrate WD. The first resin material CL_I1 may be cured in case that the first resin material CL_I1 is exposed to the UV light. In case that the curing device UVM applies ultraviolet (UV) light toward the first surface S1, the UV light may not pass through a light blocking material BM disposed on the protective layer WPF. For example, a portion of the first resin material CL_I1 that overlaps the light blocking material BM may not be cured.

According to an embodiment, the curing device UVM may apply ultraviolet (UV) light toward the second surface S2. The light blocking material BM, which blocks the UV light, may not be disposed on the second surface S2, and therefore all of the first resin material CL_I1 may be cured. The cured first resin material CL_I1 may form the first preliminary cover layer CL1_I and the third preliminary cover layer CL3_I. For example, the cured first resin material CL_I1 may form the upper preliminary cover layer UCL_I.

Referring to FIGS. 6 and 13A to 15B, a lower cover layer CL2 may be formed on the base substrate WD (S400). The lower cover layer CL2 may cover the second surface S2.

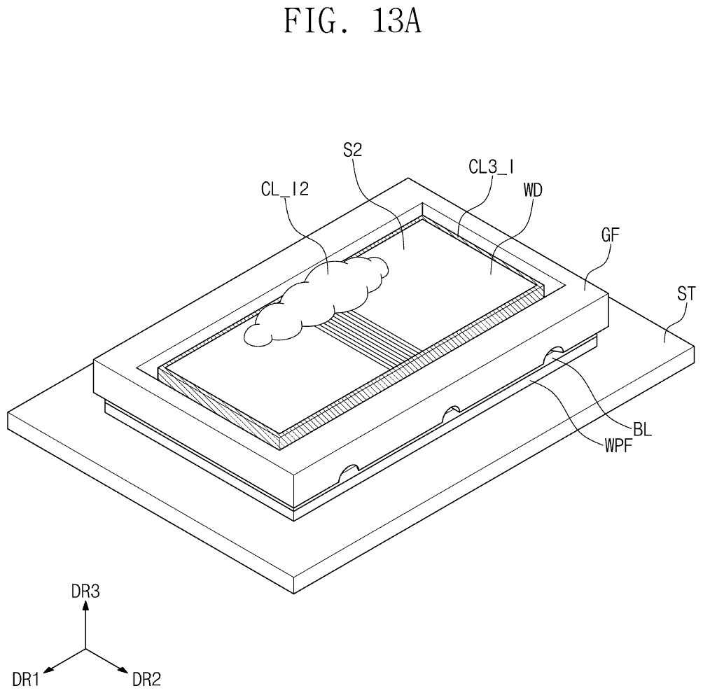

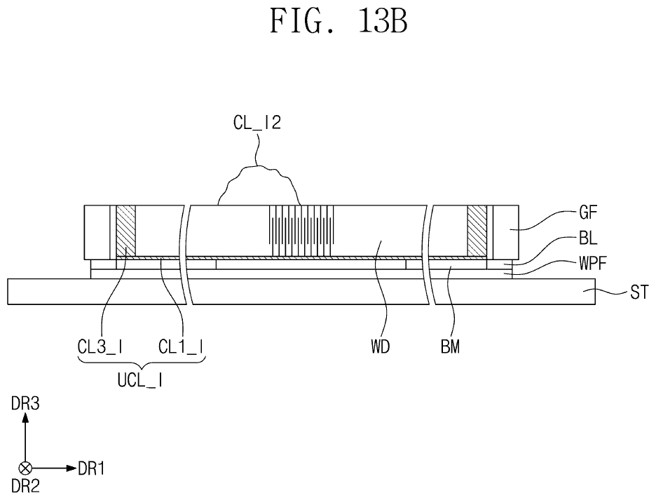

Referring to FIGS. 6, 13A, and 13B, the carrier film CAF (refer to FIG. 12B) may be removed from the guide film GF and the base substrate WD. The second surface S2 of the base substrate WD may be exposed to the outside. In a process of forming the lower cover layer CL2, the protective layer WPF may function as a rear carrier film.

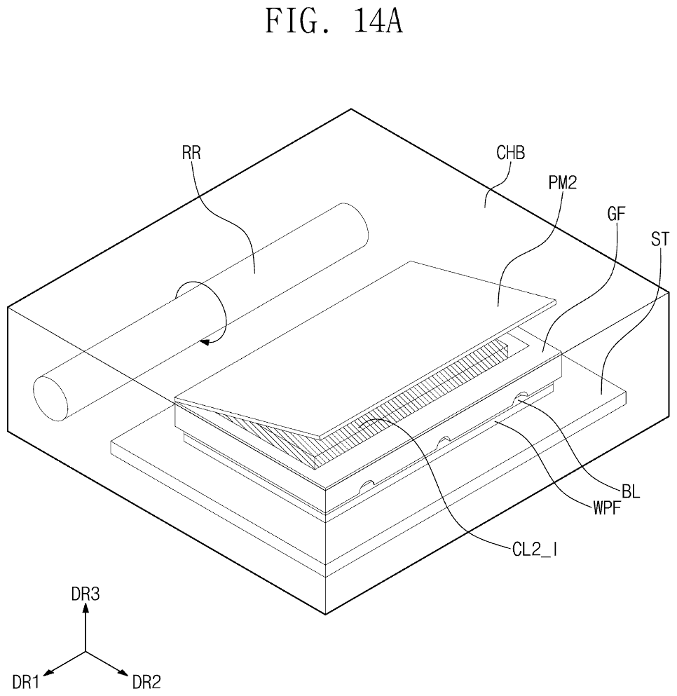

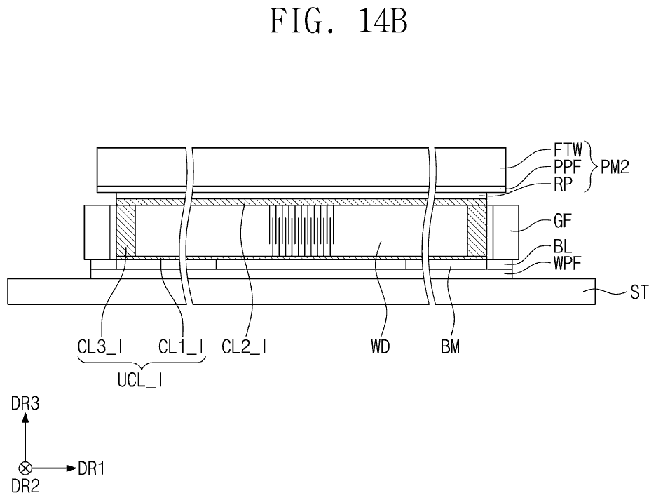

A second resin material CL_I2 may be applied to the second surface S2 of the base substrate WD. For example, the second resin material CL_I2 may be evenly applied to the second surface S2, and a portion of the second resin material CL_I2 may be applied to the upper surface of the third preliminary cover layer CL3_I. The second resin material CL_I2 applied to the second surface S2 and the upper surface of the third preliminary cover layer CL3_I may form a second preliminary cover layer CL2_I (refer to FIG. 14B). The second preliminary cover layer CL2_I may be referred to as a lower preliminary cover layer CL2_I.

Referring to FIGS. 6, 14A, and 14B, a second protective module PM2 may be disposed on the second resin material CL_I2. As illustrated in FIG. 14A, the second protective module PM2 may be disposed with an inclination on the base substrate WD to which the second resin material CL_I2 is applied. The second protective module PM2 may include a release paper film RP, a protective film PPF, and a planarization substrate FTW.

The release paper film RP may be disposed on the second preliminary cover layer CL2_I. The release paper film RP may be temporarily attached and then removed. For example, the release paper film RP may be attached to the second cover layer CL2 (refer to FIG. 17) in case that the window module WM is manufactured and may be removed in a step of attaching the window module WM and the display module DM to each other. The protective film PPF may be disposed between the planarization substrate FTW and the release paper film RP and may prevent damage to the release paper film RP. The planarization substrate FTW may be a component disposed at the top of the second protective module PM2.

The upper surface of the second protective module PM2 may be rolled by the roller RR. For example, the roller RR may roll the upper surface of the planarization substrate FTW. Thus, the release paper film RP may be disposed in close contact with the second resin material CL_I2. By using the planarization substrate FTW, constant pressure may be evenly applied to the entire surface to which the second resin material CL_I2 is applied. The rolling process may be performed in the chamber CHB. The inside of the chamber CHB may be in a vacuum state.

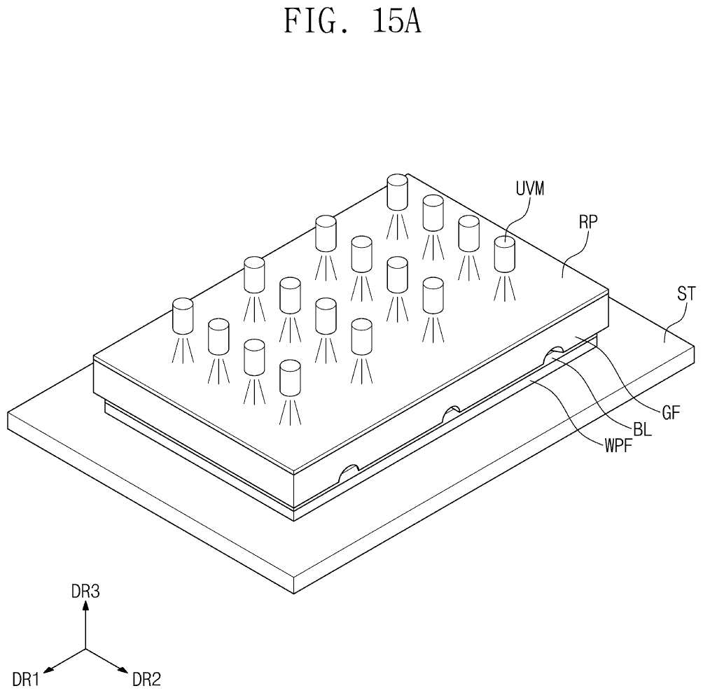

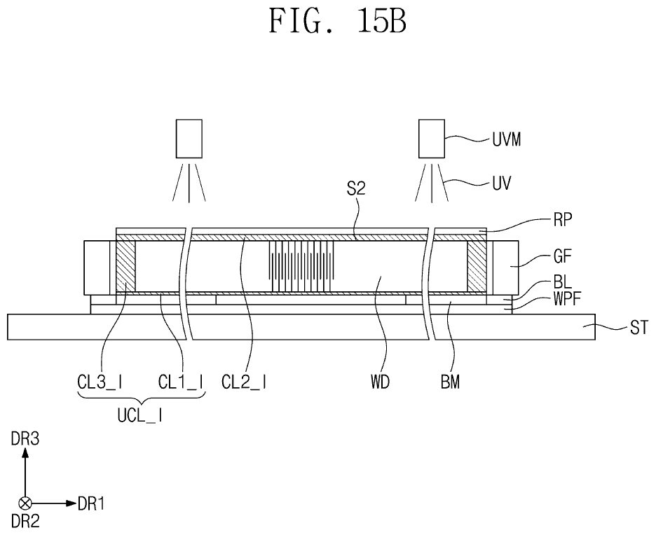

Referring to FIGS. 6, 15A, and 15B, the planarization substrate FTW may be removed from the release paper film RP. At this time, the protective film PPF may also be removed from the release paper film RP. The protective film PPF disposed between the planarization substrate FTW and the release paper film RP may prevent damage to the window module WM that is like to occur in the rolling process and the process of removing the planarization substrate FTW.

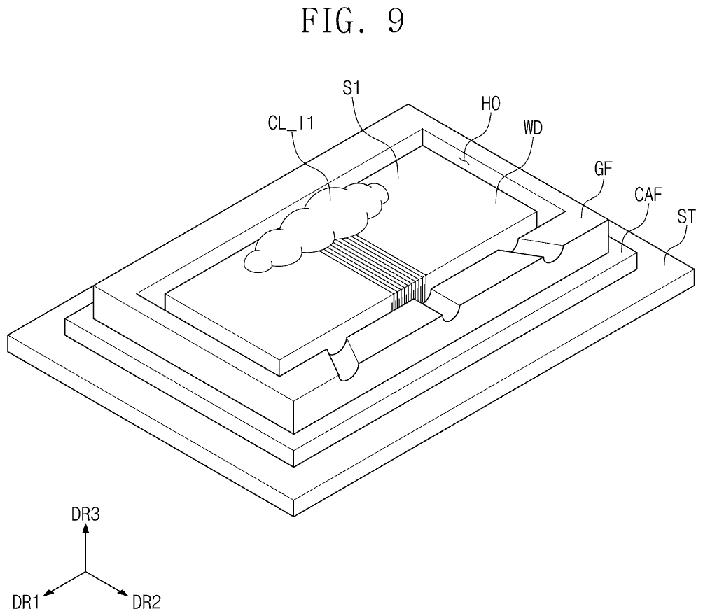

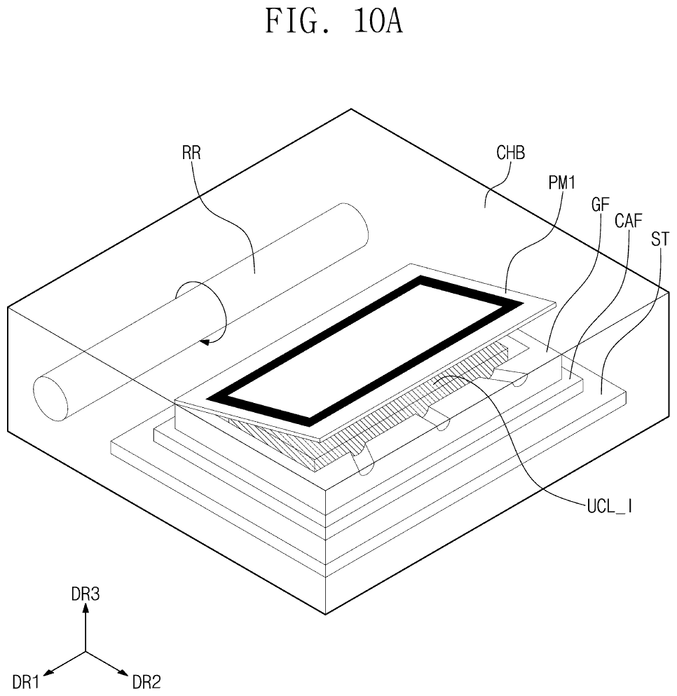

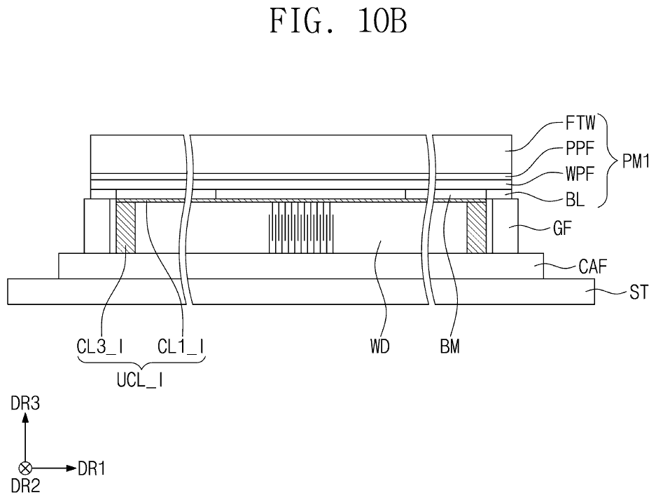

The second resin material CL_I2 may be cured by the curing device UVM. The curing device UVM may apply ultraviolet (UV) light toward the second surface S2 of the base substrate WD. The second resin material CL_I2 may be cured in case that the second resin material CL_I2 is exposed to the UV light. Unlike in the process of curing the first resin material CL_I1 (refer to FIG. 9), a material, through which the UV light does not pass, may not be disposed on the second surface S2. The curing process may be performed without turning the protective layer WPF, the base substrate WD, and the release paper film RP upside down. The cured second resin material CL_I2 may form the second preliminary cover layer CL2_I. For example, the cured second resin material CL_I2 may form the lower preliminary cover layer CL2_I.

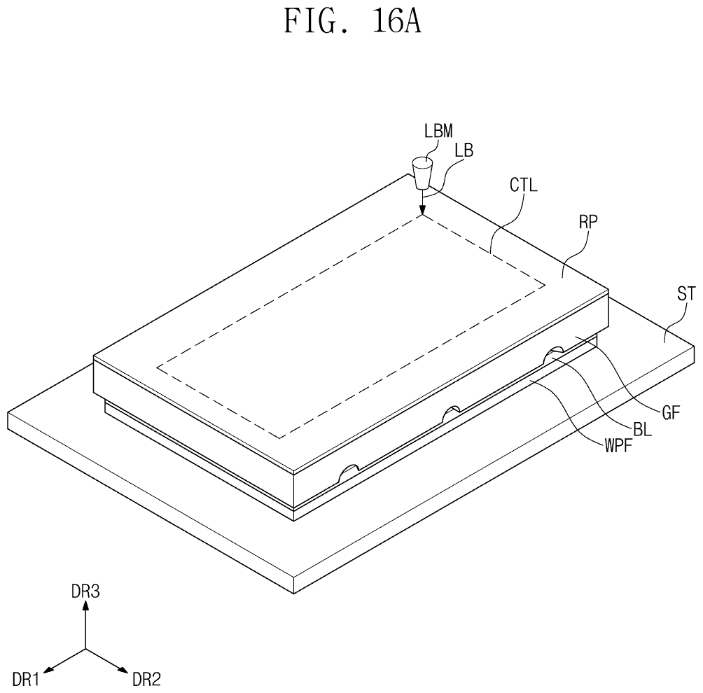

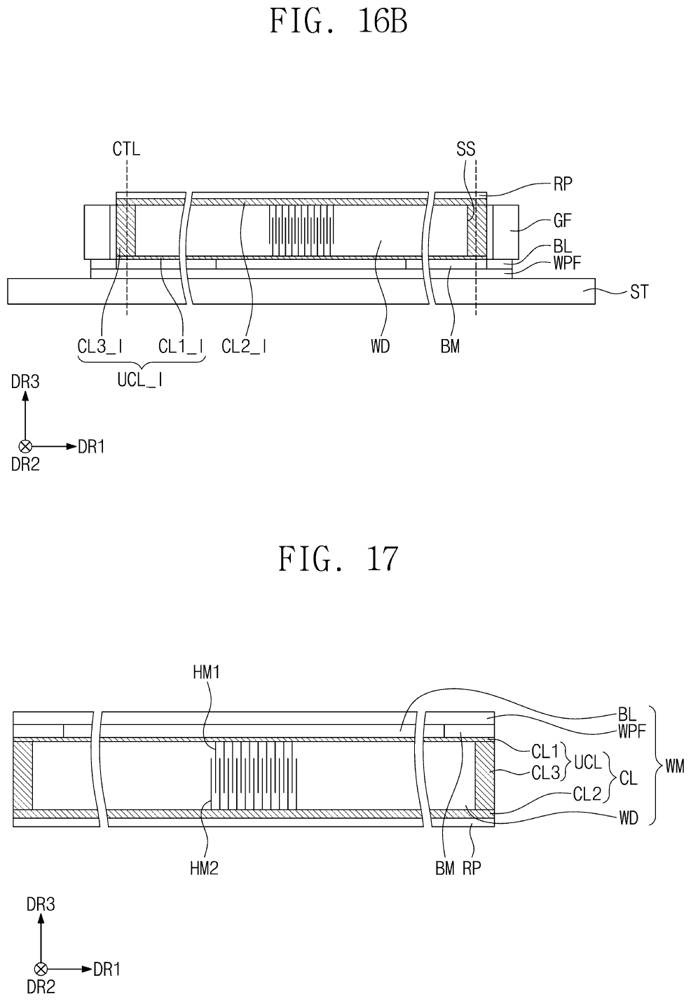

Referring to FIGS. 6, 16A, and 16B, a portion of the upper preliminary cover layer UCL_I and a portion of the lower preliminary cover layer CL2_I may be cut along a cutting line CTL (S500). A laser device LBM may apply a laser beam LB to perform the cutting. The cutting line CTL may be spaced apart from the side surfaces SS. The length of the cutting line CTL may be longer than the perimeter of the base substrate WD. For example, the laser beam LB may be applied to an area overlapping the third preliminary cover layer CL3_I, and may not be applied to the base substrate WD. According to an embodiment, by cutting the first to third preliminary cover layers CL1_I, CL2_I, and CL3_I without cutting the base substrate WD, damage to the base substrate WD may be prevented.

FIG. 17 is a schematic sectional view illustrating a window module WM and a release paper film RP according to an embodiment. The window module WM of FIG. 17 may be a window module WM manufactured by the window module manufacturing method described with reference to FIGS. 6 to 16B. In describing FIG. 17, the description will be made with reference to FIG. 3A, and redundant descriptions of identical reference numerals will be omitted for descriptive convenience.

Referring to FIG. 17, the window module WM may include a protective layer WPF, an adhesive layer BL, a window WD, and a cover layer CL. In case that the cover layer CL has an excellent adhesive force, the adhesive layer BL may be omitted. For example, the window module WM may include the protective layer WPF, the window WD, and the cover layer CL.

The cover layer CL may include an upper cover layer UCL and a lower cover layer CL2. The upper cover layer UCL may include a first cover layer CL1 and a third cover layer CL3. The upper cover layer UCL may be formed by cutting a portion of a first preliminary cover layer CL1_I (refer to FIG. 16B) and a portion of a third preliminary cover layer CL3_I (refer to FIG. 16B). The lower cover layer CL2 may be referred to as a second cover layer CL2. The lower cover layer CL2 may be formed by cutting a portion of a second preliminary cover layer CL2_I (refer to FIG. 16B).

The impact strength of the window module WM manufactured according to an embodiment may be measured by pen drop evaluation or two-point bending evaluation.

The pen drop evaluation may be an evaluation method of placing the window module WM to be evaluated on a granite plate and measuring the height in the event of failure by dropping a specimen. The failure height of the folding area FA (refer to FIG. 3A) of the window module WM may be increased by about 10 cm or more, compared to that of a window in the related art. As the window module WM has a pattern structure formed by first grooves HM1 and second grooves HM2, the failure height may be about 29 cm based on a folding portion, and as the window module WM has a structure in which the cover layer CL covers the pattern structure, the failure height may be increased by about 1 cm to about 4 cm. For example, the window module WM in which the cover layer CL covers the pattern structure may have a failure height of about 30 cm and up to about 33 cm. The structure of the window module WM may alleviate the amount of impact, and thus the impact resistance may be improved.

In the pen drop evaluation, the specimen may have a weight of about 5.8 g and may have a ball shape having a diameter of about 0.3 mm. However, the shape and weight of the specimen are not limited thereto. Furthermore, the failure heights of the first and second non-folding areas NFA1 and NFA2 of the window module WM may be about 1 m or more.

The two-point bending evaluation is an evaluation method of placing the folded window module WM between two plates and measuring a broken inner diameter and a repulsive force with decreasing the gap between the two plates. In case that the window module WM has an inner diameter of about 1.5 mm, the window module WM may achieve a low repulsive force and a reduction in the broken inner diameter, compared to a window in the related art. For example, the window module WM having a thickness of about 200 micrometers to about 400 micrometers may have a repulsive force similar to, or lower than, that of the window WD in the related art that has a thickness of about 30 micrometers.

As described above, the first grooves HM1 and the second grooves HM2 may be formed in the window WD overlapping the folding area FA. Thus, a repulsive force applied to the folding area FA in the folded state of the display device ED may be decreased, and a tensile force may be increased.

The cover layer CL having a refractive index similar to the refractive index of the window WD may cover the window. Thus, the first grooves HM1 and the second grooves HM2 formed in the window WD may not be visible from the outside. For example, the cover layer CL may have a structure surrounding the window WD. Thus, the impact resistance of the window module WM may be improved, and the thick window module WM may have a low repulsive force.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a display module including a folding area; and
a window module disposed on the display module, wherein
the window module includes:
a base substrate including a first surface on which a plurality of first grooves are formed and a second surface on which a plurality of second grooves are formed,
a first cover layer disposed on the first surface of the base substrate and filled in the plurality of first grooves; and
a second cover layer disposed on the second surface of the base substrate and filled in the plurality of second grooves, and
depths of the plurality of first grooves and the plurality of second grooves are greater than or equal to half of a distance between the first surface and the second surface of the base substrate.

2. The display device of claim 1, wherein
the window module further includes a third cover layer covering a plurality of side surfaces of the base substrate, the plurality of side surfaces of the base substrate connecting the first surface and the second surface of the base substrate, and
the base substrate is covered by the first cover layer, the second cover layer, and the third cover layer.

3. The display device of claim 2, wherein refractive indexes of the first cover layer, the second cover layer, and the third cover layer are in a range of about 1.49 to about 1.53.

4. The display device of claim 2, wherein Poisson's ratios of the first cover layer, the second cover layer, and the third cover layer are in a range of about 0.3 to about 0.6.

5. The display device of claim 2, wherein Young's moduli of the first cover layer, the second cover layer, and the third cover layer are in a range of about 20 kPa to about 50 kPa.

6. The display device of claim 2, wherein volumetric strains of the first cover layer, the second cover layer, and the third cover layer are in a range of about 5% to about 20% in case that the display module and the window module are folded.

7. The display device of claim 2, wherein the first cover layer and the second cover layer are thinner than the third cover layer.

8. The display device of claim 2, wherein
the first cover layer and the second cover layer have a thickness of about 20 micrometers to about 40 micrometers, and
the third cover layer has a thickness of about 90 micrometers to about 110 micrometers.

9. The display device of claim 1, wherein a plurality of concave grooves are recessed toward the plurality of second grooves, respectively, and are formed in the second cover layer in a folded state in which the display module and the window module are folded.

10. The display device of claim 9, wherein depths of the plurality of concave grooves are smaller than depths of the plurality of second grooves.

11. The display device of claim 1, wherein widths of the plurality of first grooves and widths of the plurality of second grooves are decreased as being closer to first bottom surfaces of the plurality of first grooves and second bottom surfaces of the plurality of second grooves.

12. The display device of claim 1, wherein the base substrate has a thickness of about 200 micrometers to about 400 micrometers.

13. The display device of claim 1, wherein
the second surface of the base substrate is disposed between the first surface of the base substrate and the display module,
the plurality of first grooves have first widths in a flat state in which the display module and the window module are flat,
the plurality of first grooves have second widths in a folded state in which the display module and the window module are folded, and
the second widths of the plurality of first grooves in the folded state are smaller than the first widths of the plurality of first grooves in the flat state.

14. The display device of claim 13, wherein
the plurality of second grooves have third widths in the flat state,
the plurality of second grooves have fourth widths in the folded state, and
the fourth widths of the plurality of second grooves in the folded state are greater than the third widths of the plurality of second grooves in the flat state.

15. A display device comprising:
a display module including a folding area; and
a window module disposed on the display module, wherein
the window module includes:
a base substrate including:
a first surface on which a plurality of first grooves are formed,
a second surface on which a plurality of second grooves are formed, and
a plurality of side surfaces connecting the first surface and the second surface;
a first cover layer disposed on the first surface of the base substrate and filled in the plurality of first grooves;
a second cover layer disposed on the second surface of the base substrate and filled in the plurality of second grooves; and
a third cover layer covering the plurality of side surfaces of the base substrate, and
the base substrate is covered by the first cover layer, the second cover layer, and the third cover layer, and
a plurality of concave grooves are recessed toward the plurality of second grooves, respectively, and are formed in the second cover layer in a folded state in which the display module and the window module are folded.

16. The display device of claim 15, wherein depths of the plurality of first grooves and the plurality of second grooves are greater than or equal to half of a distance between the first surface and the second surface.

17. The display device of claim 15, wherein depths of the plurality of concave grooves are smaller than depths of the plurality of second grooves.

18. The display device of claim 15, wherein widths of the plurality of first grooves and widths of the plurality of second grooves are decreased as being closer to first bottom surfaces of the plurality of first grooves and second bottom surfaces of the plurality of second grooves.

19. The display device of claim 15, wherein refractive indexes of the first cover layer, the second cover layer, and the third cover layer are in a range of about 1.49 to about 1.53.

20. The display device of claim 15, wherein Poisson's ratios of the first cover layer, the second cover layer, and the third cover layer are in a range of about 0.3 to about 0.6.

21. The display device of claim 15, wherein Young's moduli of the first cover layer, the second cover layer, and the third cover layer are in a range of about 20 kPa to about 50 kPa.

22. The display device of claim 15, wherein volumetric strains of the first cover layer, the second cover layer, and the third cover layer are in a range of about 5% to about 20% in case that the display module and the window module are folded.

23. The display device of claim 15, wherein
the second surface of the base substrate is disposed between the first surface of the base substrate and the display module,
the plurality of first grooves have first widths in a flat state in which the display module and the window module are flat,
the plurality of first grooves have second widths in the folded state in which the display module and the window module are folded,
the second widths of the plurality of first grooves in the folded state are smaller than the first widths of the plurality of first grooves in the flat state,
the plurality of second grooves have third widths in the flat state,
the plurality of second grooves have fourth widths in the folded state, and
the fourth widths of the plurality of second grooves in the folded state are greater than the third widths of the plurality of second grooves in the flat state.

24. The display device of claim 15, wherein
the first cover layer and the second cover layer have a thickness of about 20 micrometers to about 40 micrometers, and
the third cover layer has a thickness of about 90 micrometers to about 110 micrometers.

25. A method for manufacturing a display device, the method comprising:
forming a display module;
forming a window module; and
attaching the window module to the display module, wherein
the forming of the window module includes:
placing a base substrate on a carrier film, the base substrate including a first surface on which a plurality of first grooves are formed, a second surface on which a plurality of second grooves are formed, and a plurality of side surfaces connecting the first surface and the second surface;
attaching a guide film to the carrier film, the guide film having an opening surrounding the base substrate;
forming an upper preliminary cover layer covering the first surface and the plurality of side surfaces of the base substrate;
forming a lower preliminary cover layer covering the second surface; and
cutting a portion of the upper preliminary cover layer and a portion of the lower preliminary cover layer along a cutting line.

26. The method of claim 25, wherein the cutting line is spaced apart from the plurality of side surfaces.

27. The method of claim 25, wherein the forming of the upper preliminary cover layer includes:
applying a first resin material to the first surface of the base substrate,
placing a first protective module on the first resin material, the first protective module including a protective layer and a planarization substrate;
disposing the protective layer in close contact with the first resin material by rolling an upper surface of the first protective module;
removing the planarization substrate from the protective layer;
turning the carrier film, the base substrate, and the protective layer upside down such that positions of the first surface and the second surface are interchanged; and
curing the first resin material.

28. The method of claim 27, wherein
the first protective module further includes an adhesive layer, and
the adhesive layer is disposed under the protective layer.

29. The method of claim 25, wherein the forming of the lower preliminary cover layer includes:
removing the carrier film from the base substrate;
applying a second resin material to the second surface of the base substrate;
attaching a second protective module to the second resin material, the second protective module including a release paper film and a planarization substrate;
disposing the release paper film in close contact with the second resin material by rolling an upper surface of the second protective module;
removing the planarization substrate from the release paper film; and
curing the second resin material.

30. The method of claim 25, wherein
a depth of the opening of the guide film is greater than or equal to a height of the base substrate, and
the base substrate is disposed in the opening of the guide film.

31. The method of claim 25, wherein the guide film includes a flow passage provided on a side surface of the guide film.

32. The method of claim 25, wherein a length of the cutting line is longer than a perimeter of the base substrate.
